(19) United States
(12) Patent Application Publication
(10) Pub. No.: US 2014/0308813 A1
(43) Pub. Date: Oct. 16, 2014

(54) METHODS AND APPARATUS FOR A NON-CONTACT EDGE POLISHING MODULE USING ION MILLING

(71) Applicant: APPLIED MATERIALS, INC., Santa Clara, CA (US)

(72) Inventors: Samuel Hsu, Palo Alto, CA (US); Hung Chen, Sunnyvale, CA (US); Jay Gurusamy, Santa Clara, CA (US); Gautam Dandavate, Sunnyvale, CA (US)

(73) Assignee: Applied Materials, Inc., Santa Clara, CA (US)

(21) Appl. No.: 13/862,696

(22) Filed: Apr. 15, 2013

(51) Int. Cl. H01L 21/67; H01L 21/306

(52) U.S. Cl. CPC H01L 21/67069; H01L 21/30625; H01L 21/67092
USPC 438/692; 156/345.13

(57) ABSTRACT

Systems, methods and apparatus for polishing a substrate edge without mechanical contact are disclosed. The apparatus includes a rotatable chuck configured to secure a substrate, an ion milling machine configured to project an ion beam on an edge of the substrate and to sputter off matter from the substrate, and an endpoint detection sensor configured to determine if a material removal endpoint of the substrate has been reached. Numerous additional features are disclosed.

### FIELD

The present invention generally relates to chemical mechanical planarization (CMP) systems, and more particularly is directed to methods and apparatus for polishing a substrate edge.

### BACKGROUND

Existing substrate edge polishing systems typically use a tape or film media impregnated with an abrasive that is drawn across the edge of the substrate to polish and shape the edge into a desired profile. Note that the edge of the substrate includes the outer edge formed by a bevel from the major surface of the substrate and an edge exclusion region that extends radially from the bevel toward the center of the major surface. Contact-based edge polishing systems are typically wet systems that consume the polishing tape and deionized (DI) water and/or polishing chemicals. Thus, the operating costs of conventional edge polishing systems include the cost of the consumables. Further, the edge exclusion region can be difficult to isolate based on the geometry of conventional edge polishing systems. In other words, conventional edge polishing systems may not be able to separately polish only the edge exclusion region. Additionally, the accuracy of using an abrasive tape for polishing imposes some practical limitations that may desire using different grit abrasive tapes (with different and varying removal rates) which also may necessitate several steps in a polishing process as the abrasive tapes are replaced. Thus, what is needed are methods and apparatus that enable edge polishing with reduced operating costs, improved accuracy, control, and/or isolation over the polishing process.

### SUMMARY

Inventive methods and apparatus are provided for non-contact edge polishing of substrates. In some embodiments, the present invention uses ion milling (e.g., using an Argon ion beam) to provide precise control and accuracy of removal of material from the substrate edge without risking damage to the substrate that conventional methods can introduce. A substrate to be processed is loaded into an evacuated chamber and mounted on a rotating chuck (e.g., an electrostatic or vacuum chuck). The edge of the substrate is aligned with an ion beam projected onto the edge of the substrate using a capture ring and/or one or more sensors. The substrate is rotated while the ion beam sputters off material from the substrate's edge. An optical sensor can be employed for end point detection and a shield such as a tubular mask can be employed to prevent sputtered off particles from landing on the major surface of the substrate.

In some embodiments, a system is provided that includes a rotatable chuck configured to secure a substrate; an ion milling machine configured to project an ion beam on an edge of the substrate and to sputter off matter from the substrate; and an endpoint detection sensor configured to determine if a material removal endpoint of the substrate has been reached. Numerous additional features are disclosed.

In other embodiments, a method is provided that includes loading a substrate onto a rotatable chuck so that an edge of the substrate is aligned with an ion gun of an ion milling machine; sputtering off material from the edge of the substrate as the substrate is rotated by the chuck; and determining if an endpoint of material removal has been reached using a sensor disposed over the edge of the substrate.

In some embodiments, a system is provided that includes a processor; and a memory coupled to the processor and storing processor executable instructions to control a plurality of components to load a substrate onto a rotatable chuck so that an edge of the substrate is aligned with an ion gun of an ion milling machine; sputter off material from the edge of the substrate as the substrate is rotated by the chuck; and determine if an endpoint of material removal has been reached using a sensor disposed over the edge of the substrate.

Numerous other aspects are provided. Other features and aspects of the present invention will become more fully apparent from the following detailed description, the appended claims and the accompanying drawings.

### BRIEF DESCRIPTION OF THE DRAWINGS

FIG. 1 illustrates a schematic block diagram depicting a top view of an example edge polishing system according to some embodiments.

FIG. 2 is a schematic block diagram depicting a side cross-sectional view of the example edge polishing system of FIG. 1.

FIG. 3 illustrates a schematic block diagram depicting a side cross-sectional view of an alternative example edge polishing system according to some embodiments.

FIG. 4 illustrates a flowchart depicting an example method of polishing an edge of a substrate using an edge polishing system according to some embodiments.

FIG. 5 illustrates a schematic block diagram depicting a top view of another alternative example edge polishing system according to some embodiments of the present invention.

FIG. 6 illustrates a schematic block diagram depicting a side cross-sectional view of the example edge polishing system of FIG. 5.

### DETAILED DESCRIPTION

Inventive methods and apparatus are provided for non-contact edge polishing processes and systems. In some embodiments, the present invention uses ion milling (e.g., using an Argon ion beam) to provide precise control and accuracy of removal of material from the substrate edge without risking damage to the substrate that conventional methods can introduce. A substrate to be processed is loaded into an evacuated chamber and mounted on a rotating chuck (e.g., an electrostatic or vacuum chuck). The edge of the substrate is aligned with an ion beam projected onto the edge of the substrate using a capture ring and/or one or more sensors. The substrate is rotated while the ion beam sputters off material from the substrate's edge. An optical sensor can be employed for end point detection and a shield such as a tubular mask, can be employed to prevent sputtered off particles from contaminating the major surface of the substrate.

Optimizing material removal rates from the edge (e.g., up to 10 mm from the outer edge) of a substrate while polishing the substrate using conventional chemical mechanical planarization (CMP) methods presents a number of challenges since conventional removal mechanisms and techniques are dependent on many dynamic variables. The present invention provides a novel method of edge profile optimization that is separate from the CMP process and localized to the edge of the substrate. Instead of contacting the substrate edge with a polishing media, the present invention uses ion milling to polish the substrate edge. In some embodiments, the system of the present invention operates at atmosphere and in others; the system is contained in a sealable chamber and can be operated in a vacuum. The desired level of repeatability and removal rate can dictate whether a sealable chamber and/or a vacuum are used. In some embodiments, removal rate tuning can be controlled by adjusting the incident beam angle, the beam aperture, and/or the kinetic energy of the beam.

In addition, embodiments of the present invention allow for cost effective removal of any non-uniformities occurring at the edge of the substrate that can be introduced by conventional CMP processes. Embodiments of the present invention may also eliminate the cost burden of having to use consumable materials and components such as polishing tape, polishing pads, and slurry. Further, since method embodiments of the present invention do not require mechanical polishing of the substrate edge, potential damage to the substrate is avoided. This is particularly relevant to thin (e.g., less than approximately 50 μm) substrate applications such as fragile “Through Silicon Via” (TSV) substrates that are vulnerable to and easily damaged by any edge contact.

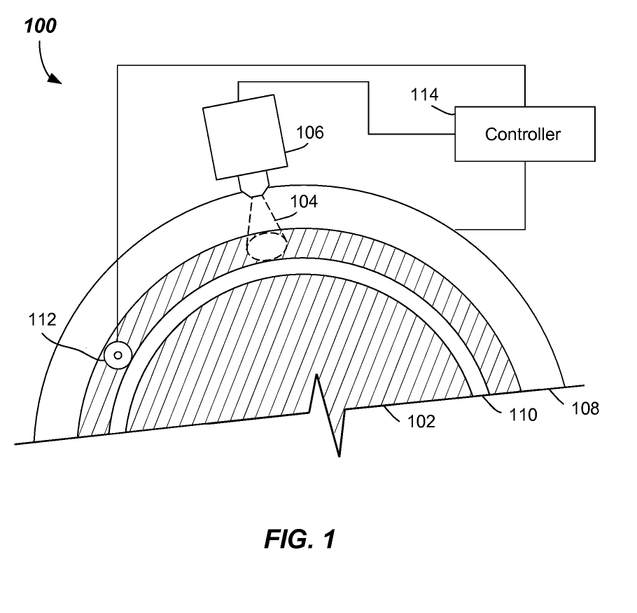

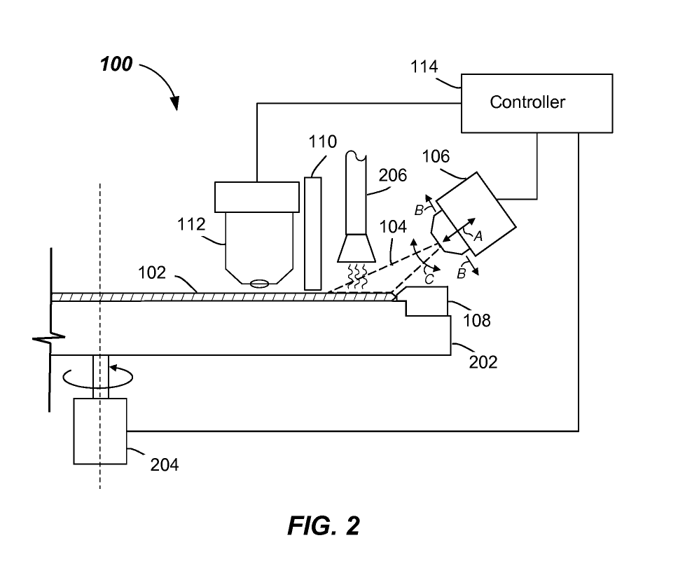

Turning to FIGS. 1 and 2, an example embodiment of a non-contact edge polishing system 100 is illustrated. FIG. 1 depicts a top view and FIG. 2 depicts a side view of the system 100. In some embodiments, the system 100 rotates the edge of a substrate 102 under an ion beam 104 projected by an ion milling machine 106 that includes an adjustable ion gun. The system 100 can accommodate any size substrates, including for example, substrates ranging from approximately 100 mm to approximately 900+ mm. Larger size substrates can be processed as well. The edge of the substrate 102 to be milled can be from approximately 0 mm to approximately 10 mm.

Although not represented in the drawings for clarity sake, the system 100 can include an appropriate sized, sealable chamber suitable to house the components of the system and to accommodate the desired size substrates. The chamber can include one or more ports and robot arms for loading and unloading substrates. In addition, the system chamber can include pumps to create a vacuum within.

The substrate 102 is positioned under the beam 104 via the use of a capture ring 108. The capture ring 108 can be made of ceramic and function to both center the substrate 102 and protect the surfaces supporting the substrate 102 from the ion beam 104. In some embodiments, the capture ring 108 can be a replaceable/consumable component. As shown most clearly in the cross-section profile depiction of FIG. 2, the top of the capture ring 108 can include a inwardly, downwardly sloping surface to kinematically guide and facilitate proper positioning of the substrate 102 deposited there on.

In some embodiments, the ion milling machine 106 used can be a commercially available ion milling machine such as, for example, the model IM4000 Argon ion milling system manufactured by Hitachi High Technologies America, Inc., a Delaware corporation. However, other practicable ion milling systems can be used. Conventionally, such ion milling machines have been used to thin samples until they are transparent to electrons. By making a sample electron transparent, the sample can be imaged and characterized in a transmission electron microscope (TEM). Ion beam milling has also been used for cross-section preparation for use with scanning electron microscope (SEM) analysis of materials. Thus, all known prior applications of ion milling machines were limited to sample thinning for TEM imaging and preparation for SEM analysis.

A shield 110 (e.g., a tubular mask) is disposed between the edge of the substrate and the remainder of the major surface of the substrate to block particles sputtered off of the edge from reaching the center of the substrate 102. The shield can be made from roughened ceramic or ceramic coated material. In some embodiments, the shield 110 can be a replaceable/consumable component. In some embodiments, the shield 110 may be held slightly above the substrate (e.g., approximately 0.5 mm to approximately 5 mm above) or, in other embodiments, the shield may rest on the substrate 102 and rotate with the substrate 102.

A sensor 112 (e.g., an optical sensor) is used to detect the polishing end point. An example of a commercially available optical sensor suitable for use with the system of the present invention is the model SD1024GL sensor manufactured by Verity Instruments, Inc., headquartered in Texas. In some embodiments, inductive sensors may be used. Other practicable sensors may also be used. The system 100 can be operated by a controller 114 (e.g., a processor, computer, embedded controller, programmable logic array, microprocessor, discrete logic, etc.) configured, or programmed to execute software/instructions, to perform the methods of the present invention.

The substrate 102 is rotated on a chuck 202 driven by a motor 204 or any other suitable actuator. The chuck 202 can be made from, for example, a ceramic encased or coated electrode or an electrode embedded in a polymer film. In some embodiments, an aluminum nitride bonded copper electrode can be used. An example of a ceramic coated electrode is a plasma sprayed aluminum oxide on an aluminum electrode. An example an electrode embedded in a polymer film is a copper electrode embedded in polyimide film. In some embodiments, the chuck 202 can include a substrate holding mechanism such as an electrostatic device or vacuum pressure ports to maintain the substrate's position as the substrate 102 is rotated. In some embodiments, the chuck can include thermal control devices to pre-heat the substrate 102 or cool the substrate 102 during processing. Thus, the thermal control devices may include heating elements and/or channels for cooling fluids (e.g., liquids or gases). In some embodiments, helium can be dispensed between the chuck 202 and the substrate 102 for both cooling and to provide a conductive layer.

The chuck 202 may be driven by a motor 204 coupled directly or through a linkage to the lower center of the chuck 202. In some embodiments, other components and arrangements for rotating the chuck 202 may be employed such as drive wheels at the perimeter of the chuck 202. An example motor 204 that can be employed is a 0.5 HP electric motor configured to rotate the chuck 202 at approximately 1 rpm to approximately 100 rpm. Other types of, power, and speed motors can be used.

In addition to pumps for creating a vacuum in the system chamber, the system 100 of the present invention may also include a ventilation system 206. The ventilation system 206 can include a hood or intake nozzle disposed proximate to the substrate 102 near the sputtering activity of the ion beam 104 as shown in FIG. 2 (omitted from FIG. 1 for clarity). The ventilation system 206 may apply suction to evacuate sputtered material before redeposition on system chamber surfaces or on the substrate 102. The ventilation system 206 can be exhausted outside of the shield and outside the system chamber.

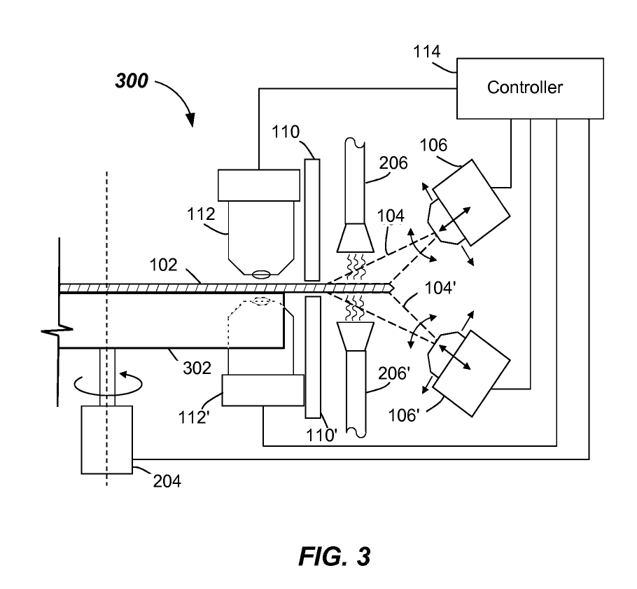

FIG. 3 depicts an example of an alternative embodiment of the present invention. As shown in FIG. 3, the system 300 of the alternative embodiment allows both sides of the substrate 102 to be milled concurrently. The diameter of the chuck 302 is smaller than the substrate 102 such that the substrate 102 overhangs the chuck 302 with both the top and bottom edge surfaces exposed. The system 300 includes additional components (e.g., a second ion milling machine 106′, a second sensor 112′, a second shield 110′, and a second ventilation system 206′) to facilitate the concurrent milling.

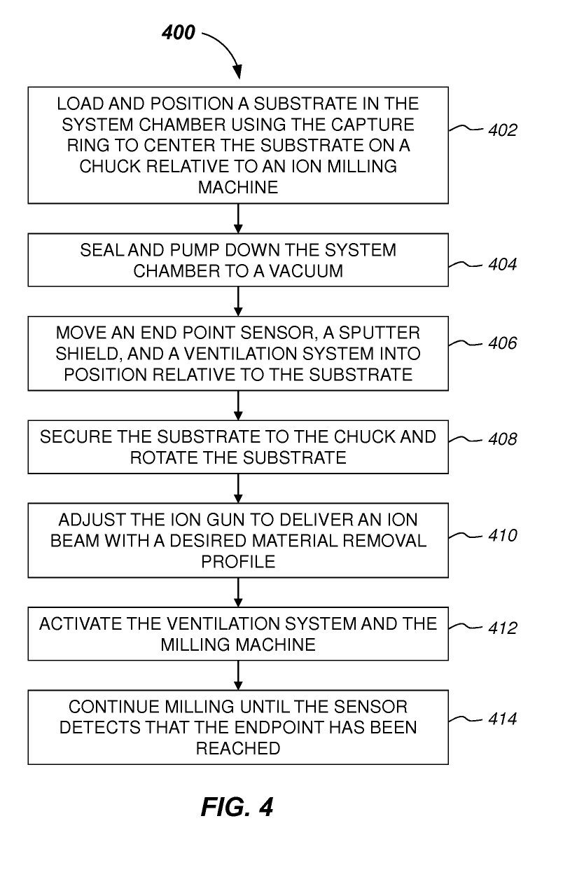

Turning now to FIG. 4, an example method 400 of the system 100 of the present invention is described in a flowchart. In operation, the system 100 can be used to remove any non-uniformities formed or otherwise occurring on the edge of a substrate 102, particularly those incurred from CMP processing. As mentioned above, operation of the system 100 can be directed by the controller 114. After the substrate 102 is loaded into the system chamber and placed on the chuck 202, using the capture ring 108 to insure proper centering on the chuck 202 and alignment with the milling machine 106 (402), the chuck 202 can be used to secure the substrate 102 and optionally pre-heat the substrate 102 while the system chamber is sealed and pumped down to the desired level of vacuum (404). The sensor 112, the shield 110, and the ventilation system can then be moved into position above the substrate (406). As the chuck 202 begins to rotate (408), the ventilation system 206 is activated and the position of the ion gun of the milling machine 106 is adjusted to create a desired material removal profile (410).

In some embodiments, as indicated by Arrows A, B, and C, the position of the ion gun of the milling machine 106 can be adjusted to facilitate creating the desired material removal profile. The adjustments to the ion gun allow the position, shape, size, and energy concentration of an ion beam spot projected on the substrate edge to be precisely configured to achieve the desired material removal profile.

Arrow A indicates that the ion gun can be moved closer to, or further from, the surface of the substrate edge. This adjustment can be used to control the projected area and the amount of energy that is delivered to the substrate edge and therefore the material removal rate. Arrows B indicate that the ion gun can be moved in a direction perpendicular to the directions of double-ended Arrow A. This adjustment can be used to move the beam to and from the outer edge of the substrate 102, i.e., radially relative to the center of the substrate 102. By oscillating the ion gun at an appropriate rate in the B directions while rotating the substrate during milling, an edge area larger than the ion beam spot can be polished. Arcing Arrow C indicates the rotational angle adjustability of the ion gun that allows for adjustment of the aspect ratio of the projected area and the size (e.g., area) of the ion beam spot. While not represented in the drawings, the aperture of the ion gun can also be adjusted (e.g., dilated) in some embodiments. Adjustment of the ion gun's aperture allows control over the size of the ion beam spot which affects the energy concentration of the ion beam and thus, the material removal rate.

In some embodiments, the ion gun of the milling machine 106 can be disposed over the center of the substrate 102, pointing radially outward toward the edge of the substrate. In such embodiments, a horizontally disposed shield or mask can be held over or on the portion of the major surface of the substrate 102 to be protected. Such embodiments may reduce the amount of redepostion on the substrate. Likewise, in some embodiments, the ion gun of the milling machine 106 can be disposed so that the beam is aimed in a direction that is parallel with a line tangential to the substrate.

Once the ion gun of the milling machine 106 is adjusted to provide the desired material removal profile and the substrate 102 is being rotated by the chuck 202, the ion milling machine is activated and material is sputtered off the surface of the substrate's edge (412). Meanwhile, the ventilation system 206 evacuates the sputtered material, the shield 110 blocks the sputtered material from reaching the center of the substrate 102, and the capture ring 108 blocks the ion beam 104 from milling the chuck 202. The temperature of the substrate can be controlled via the cooling facilities in the chuck 202 to keep the substrate 102 within a desired thermal range. As the milling continues, the sensor 112 is used by the controller 114 to detect the amount of material that has been removed and whether a desired pre-defined endpoint has been reached (414). In some embodiments, the end point can include a flatness variation specification and/or a substrate thickness definition.

In some embodiments, the same substrate edge may be exposed to multiple ion beams concurrently. For example, two or more ion guns may be aimed at adjacent areas on the same surface of the substrate edge. In addition to increasing the material removal rate, having more than one ion beam can provide greater flexibility and more options in defining and implementing the desired material removal profile.

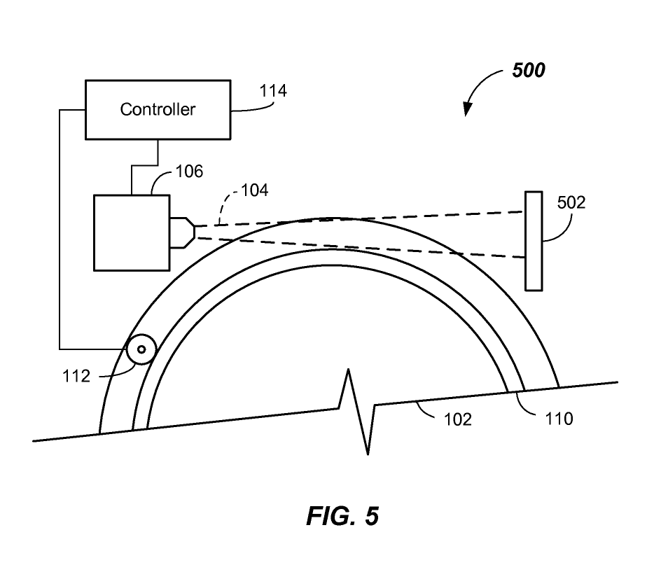

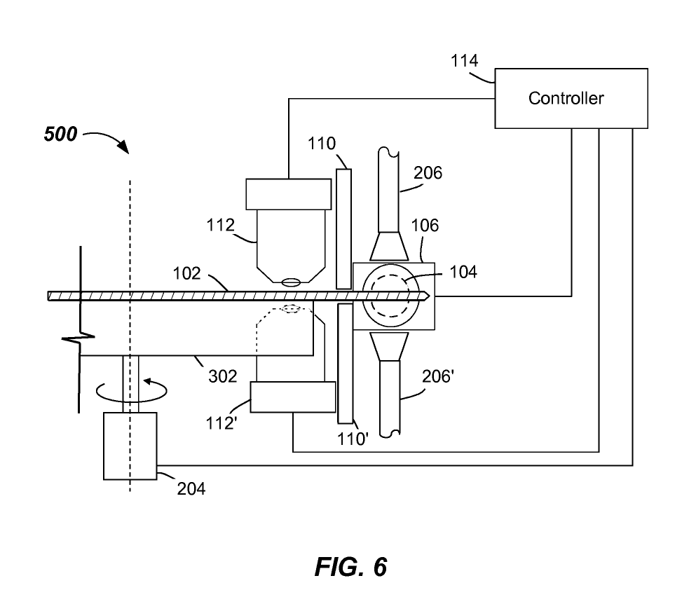

FIGS. 5 and 6 depict an example of another alternative embodiment of the present invention. FIG. 5 depicts a top view and FIG. 6 depicts a side view of the alternative system 500. As shown in FIGS. 5 and 6, the system 500 of the additional alternative embodiment allows both sides of the substrate 102 to be milled concurrently. The diameter of the chuck 302 is smaller than the substrate 102 such that the substrate 102 overhangs the chuck 302 with both the top and bottom edge surfaces exposed. The system 500 includes additional components (e.g., a second sensor 112′, a second shield 110′, and a second ventilation system 206′) to facilitate the concurrent milling. However, the system 500 only uses a single ion milling machine 106.

In this embodiment, the ion beam 104 is projected at a substantially zero incidence angle relative to the top and bottom surfaces of the substrate edge (e.g., substantially parallel to the surface of the substrate edges) and parallel to a line tangential to the major surfaces of the substrate. In FIG. 6, the ion beam 104 is aimed at the viewer, coming out of the page.

In some embodiments, the ion beam 104 can be collimated to project with less spread. In some embodiments, the ion gun may include a horizontal bar mask (e.g., having a thickness slightly thinner than the thickness of the substrate 102) across the aperture that prevents the ion beam from hitting most of the outer edge (and bevel) of the substrate while allowing the ion beam 104 to mill layers off of the edge surfaces of the substrate. In some embodiments, the system 500 may also include an absorption target 502 to capture parts of the ion beam 104 that do not hit the substrate 102.

Accordingly, while the present invention has been disclosed in connection with the preferred embodiments thereof, it should be understood that other embodiments may fall within the scope of the invention, as defined by the following claims.

The invention claimed is:

1. A substrate edge polishing system comprising:
a rotatable chuck configured to secure a substrate;
an ion milling machine configured to project an ion beam on an edge of the substrate and to sputter off matter from the substrate; and
an endpoint detection sensor configured to determine if a material removal endpoint of the substrate has been reached.

2. The substrate edge polishing system of claim 1 further comprising a sealable vacuum chamber configured to house the system.

3. The substrate edge polishing system of claim 1 further comprising a sputter shield disposed between the ion beam and a center area of the substrate.

4. The substrate edge polishing system of claim 1 further comprising a capture ring configured to position the substrate on the chuck.

5. The substrate edge polishing system of claim 1 further comprising a ventilation system configured to evacuate matter sputtered off of the substrate edge.

6. The substrate edge polishing system of claim 1 wherein the milling machine includes an ion gun and the position of the ion gun is adjustable to define a material removal profile.

7. The substrate edge polishing system of claim 6 wherein the ion gun can be adjusted to position, shape and size an ion beam spot projected onto the substrate.

8. A method of polishing a substrate edge comprising:
loading a substrate onto a rotatable chuck so that an edge of the substrate is aligned with an ion gun of an ion milling machine;
sputtering off material from the edge of the substrate as the substrate is rotated by the chuck; and
determining if an endpoint of material removal has been reached using a sensor disposed over the edge of the substrate.

9. The method of claim 8 further comprising sealing the substrate in a vacuum chamber while material is sputtered off the edge of the substrate.

10. The method of claim 8 further comprising blocking sputtered material from redepositing on a center area of the substrate using a shield disposed between the ion gun and the center area of the substrate.

11. The method of claim 8 further comprising using a capture ring to position the substrate on the chuck.

12. The method of claim 8 further comprising using a ventilation system to evacuate matter sputtered off of the substrate edge.

13. The method of claim 8 further comprising adjusting the position of the ion gun to implement a material removal profile.

14. The method of claim 13 wherein adjusting the position of the ion gun includes adjusting the position, shape and size of an ion beam spot projected onto the substrate.

15. A system comprising:
a processor; and
a memory coupled to the processor and storing processor executable instructions to control a plurality of components to:
load a substrate onto a rotatable chuck so that an edge of the substrate is aligned with an ion gun of an ion milling machine;
sputter off material from the edge of the substrate as the substrate is rotated by the chuck; and
determine if an endpoint of material removal has been reached using a sensor disposed over the edge of the substrate.

16. The system of claim 15 wherein the instructions further include an instruction to seal the substrate in a vacuum chamber while material is sputtered off the edge of the substrate.

17. The system of claim 15 wherein the instructions further include an instruction to position a shield between the ion gun and a center area of the substrate to block sputtered material from redepositing on the center area of the substrate.

18. The system of claim 15 wherein the instructions further include an instruction to use a ventilation system to evacuate matter sputtered off of the substrate edge.

19. The system of claim 15 wherein the instructions further include an instruction to adjust the position of the ion gun to implement a material removal profile.

20. The system of claim 19 wherein the instructions further include an instruction to adjust the position, shape and size of an ion beam spot projected onto the substrate.
